(19) United States
(12) Patent Application Publication
(10) Pub. No.: US 2026/0106582 A1
(43) Pub. Date: Apr. 16, 2026

(54) OPERATIONAL AMPLIFIER WITH BUILT-IN CAPACITOR MULTIPLIER

(71) Applicant: Realtek Semiconductor Corp., HsinChu (TW)

(72) Inventors: Yi Feng, HsinChu (TW); Chuan-Chu Liu, HsinChu (TW)

(73) Assignee: Realtek Semiconductor Corp., HsinChu (TW)

(21) Appl. No.: 19/347,678

(22) Filed: Oct. 1, 2025

(30) Foreign Application Priority Data
Oct. 16, 2024 (TW) 113139272

(51) Int. Cl. H03F 3/45

(52) U.S. Cl. CPC H03F 3/45188; H03F 2203/45024

(57) ABSTRACT

An operational amplifier with a built-in capacitor multiplier is provided, where the operational amplifier includes an input transistor, a current mirror circuit and a capacitor. The input transistor generates an input current according to an input signal, and the current mirror circuit generates a current mirror output current on a current output terminal of the current mirror circuit according to a current mirror input current corresponding to the input current received by a current input terminal of the current mirror circuit, where the current output terminal is coupled to an amplifier output terminal of the operational amplifier. In addition, a first terminal of the capacitor is coupled to the amplifier output terminal, and a second terminal of the capacitor is coupled to the current input terminal, making an equivalent capacitance of the capacitor seen on the amplifier output terminal be multiplied by the current mirror circuit.

### BACKGROUND OF THE INVENTION

### 1. FIELD OF THE INVENTION

The present invention is related to amplifier circuits, and more particularly, to an operational amplifier with a built-in capacitor multiplier.

### 2. DESCRIPTION OF THE PRIOR ART

Amplifier circuit design requires increased capacitance on an output terminal of the amplifier circuit to ground or power, in order to push a dominant pole of the amplifier circuit toward a low frequency. Increasing the capacitance directly by increasing a size of a capacitor will result in a significant increase in a chip area occupied by the capacitor, however. In addition, although related arts propose some capacitance amplification circuits, these additional circuits increase an overall circuit area and power consumption.

Thus, there is a need for a novel amplifier architecture, which can increase the capacitance on the amplifier output to ground without introducing any side effect or in a way that is less likely to introduce side effects.

### SUMMARY OF THE INVENTION

An objective of the present invention is to provide an operational amplifier with a built-in capacitor multiplier, which enables an equivalent capacitance of a capacitor to be multiplied according to connection of the capacitor without increasing additional circuits.

At least one embodiment of the present invention provides an operational amplifier with a built-in capacitor multiplier. The operational amplifier comprises at least one input transistor, at least one input transistor and a capacitor. The at least one input transistor is configured to generate an input current according to an input signal. The at least one current mirror circuit is configured to generate a current mirror output current on a current output terminal of the at least one current mirror circuit according to a current mirror input current received by a current input terminal of the at least one current mirror circuit, wherein the current mirror input current corresponds to the input current, and the current output terminal of the at least one current mirror circuit is coupled to an amplifier output terminal of the operational amplifier. In addition, a first terminal of the capacitor is coupled to the amplifier output terminal, and a second terminal of the capacitor is coupled to the current input terminal, to make an equivalent capacitance of the capacitor on the amplifier output terminal be multiplied by the current mirror circuit.

The operational amplifier provided by the embodiment of the present invention can achieve the purpose of increasing the equivalent capacitance of the capacitor by coupling the capacitor between an input and an output of the current mirror circuit within the operational amplifier. As the current mirror circuit is an existing component of the operational amplifier, the capacitor multiplier formed by connection of the current mirror circuit and the capacitor will not increase additional circuit area and power consumption.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an operational amplifier with a built-in capacitor multiplier according to an embodiment of the present invention.

FIG. 2 is a diagram illustrating pushing a dominant pole of an operational amplifier toward a low frequency via a built-in capacitor multiplier according to an embodiment of the present invention.

FIG. 3 is a diagram illustrating an operational amplifier with a built-in capacitor multiplier according to an embodiment of the present invention.

FIG. 4 is a diagram illustrating a fully-differential architecture based on the operational amplifier shown in FIG. 3 which is modified according to an embodiment of the present invention.

FIG. 5 is a diagram illustrating an operational amplifier with a built-in capacitor multiplier according to an embodiment of the present invention.

FIG. 6 is a diagram illustrating a fully-differential architecture based on the operational amplifier shown in FIG. 5 which is modified according to an embodiment of the present invention.

FIG. 7 is a diagram illustrating an operational amplifier with a built-in capacitor multiplier according to an embodiment of the present invention.

FIG. 8 is a diagram illustrating a fully-differential architecture based on the operational amplifier shown in FIG. 7 which is modified according to an embodiment of the present invention.

### DETAILED DESCRIPTION

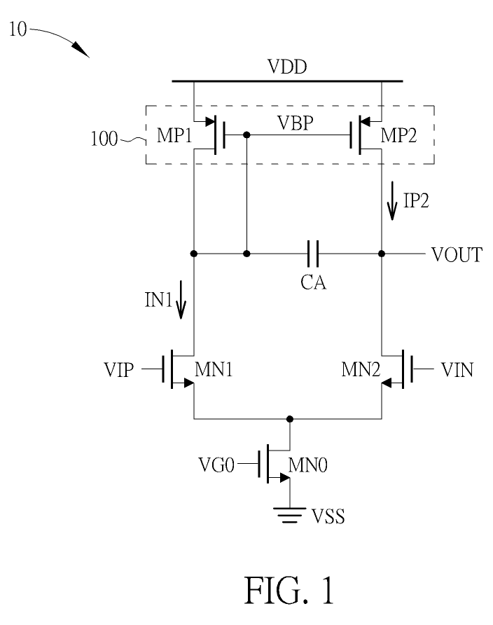

FIG. 1 is a diagram illustrating an operational amplifier 10 with a built-in capacitor multiplier according to an embodiment of the present invention. The operational amplifier 10 may comprise at least one input transistor such as N-type transistors MN1 and MN2, at least one current mirror circuit such as a current mirror circuit 100, a capacitor CA and a current source such as an N-type transistor MN0. In this embodiment, the N-type transistor MN1 and MN2 may generate an input current according to input signals on nodes VIP and VIN (e.g. the N-type transistor MN1 generates a current IN1 according to the input signal on the node VIP), and the current mirror circuit 100 may generate a current mirror output current on a current output terminal of the current mirror circuit 100 according to a current mirror input current received by a current input terminal of the current mirror circuit 100, where the current mirror input current corresponds to the input current (e.g. the current mirror input current is equal to the current IN1), and the current output terminal of the current mirror circuit 100 is coupled to an amplifier output terminal of the operational amplifier 10 (e.g. a node VOUT). In addition, a first terminal of the capacitor CA is coupled to the amplifier output terminal of the operational amplifier 10 such as the node VOUT, and a second terminal of the capacitor CA is coupled to the current input terminal of the current mirror circuit 100, to make an equivalent capacitance of the capacitor CA on the amplifier output terminal of the operational amplifier 10 (e.g. the equivalent capacitance on the node VOUT) be multiplied by the current mirror circuit 100.

In particular, the current mirror circuit 100 may comprise a first current mirror transistor such as a P-type transistor MP1 and a second current mirror transistor such as a P-type transistor MP2, where source terminals of the P-type transistors MP1 and MP2 are both coupled to a reference voltage VDD, a gate terminal of the P-type transistor MP1 is coupled to a drain terminal of the P-type transistor MP1 (as shown by a node VBP) in order to generate a control voltage on the gate terminal of the P-type transistor MP1 (e.g. a voltage on the node VBP) according to the current mirror input current (e.g. the current IN1 received by the drain terminal of the P-type transistor MP1), and a gate terminal of the P-type transistor MP2 is coupled to the gate terminal of the P-type transistor MP1 (as shown by the node VBP) in order to generate the current mirror output current (e.g. a current IP2) according to the control voltage. More particularly, the drain terminal of the P-type transistor MP1 may represent the current input terminal of the current mirror circuit 100, and a drain terminal of the P-type transistor MP2 may represent the current output terminal of the current mirror circuit 100. In this embodiment, a source terminal of the N-type transistor MN0 is coupled to a reference voltage VSS, and a voltage on a gate terminal of the N-type transistor MN0 (as shown by a node VG0) may control a current of the N-type transistor MN0. A source terminal of the N-type transistor MN1 is coupled to a drain terminal of the N-type transistor MN0, and a drain terminal of the N-type transistor MN1 is coupled to the drain terminal of the P-type transistor MP1, where a gate terminal of the N-type transistor MN1 is configured to receive a first input signal of the input signal (e.g. the input signal on the node VIP). A source terminal of the N-type transistor MN2 is coupled to the drain terminal of the N-type transistor MN0, and a drain terminal of the N-type transistor MN2 is coupled to the drain terminal of the P-type transistor MP2, where a gate terminal of the N-type transistor MN2 is configured to receive a second input signal of the input signal (e.g. the input signal on the node VIN). Under the architecture of the operational amplifier 10, the drain terminal of the P-type transistor MP2 is the amplifier output terminal of the operational amplifier 10 (as shown by the node VOUT). In this embodiment, as the P-type transistor MP1 and MP2 within the current mirror circuit 100 are typically designed to have the same size, the equivalent capacitance of the capacitor CA on the amplifier output terminal of the operational amplifier 10 (e.g. the equivalent capacitance on the node VOUT) may be twice the capacitance of the capacitor CA.

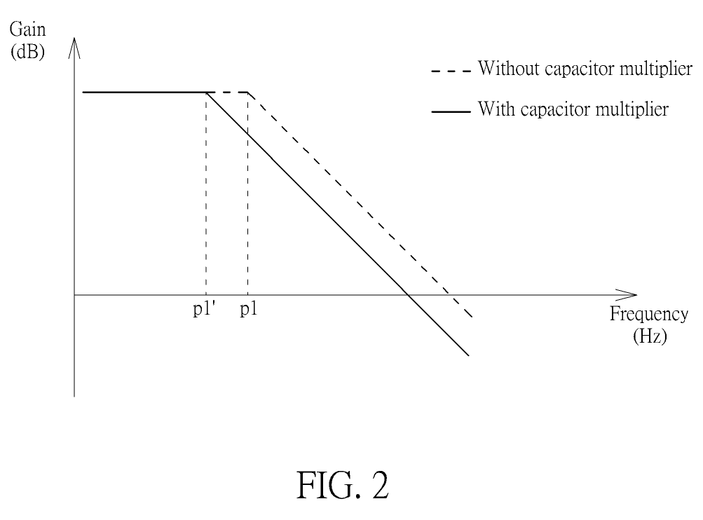

FIG. 2 is a diagram illustrating pushing a dominant pole of the operational amplifier 10 toward a low frequency via a built-in capacitor multiplier according to an embodiment of the present invention. As shown in FIG. 2, when there is no capacitor multiplier adopted in the operational amplifier 10 (e.g. the capacitor CA is coupled between the amplifier output terminal of the operational amplifier 10 such as the node VOUT and the reference voltage VSS or VDD), the dominant pole of the operational amplifier 10 is p1. When the capacitor multiplier is adopted in the operational amplifier 10 (e.g. the capacitor CA is coupled between the amplifier output terminal of the operational amplifier 10 and the current input terminal of the current mirror circuit 100, such as being coupled between the nodes VOUT and VBP), the dominant pole of the operational amplifier 10 is p1’. In comparison with the capacitor CA coupled between the nodes VOUT and the reference voltage VSS or VDD, the equivalent capacitance generated by coupling the capacitor CA between the nodes VOUT and VBP can be multiplied, and therefore the dominant pole p1’ can be at a lower frequency in comparison with the dominant pole p1. Thus, if the dominant pole needs to be designed at a designated frequency, coupling the capacitor CA between the nodes VOUT and VBP can effectively save the required area of the capacitor CA.

It should be noted that the architecture of the operational amplifier 10 shown in FIG. 1 is for illustrative purposes only, and is not meant to be a limitation of the present invention. More particularly, as long as the first terminal and the second terminal of the capacitor CA are respectively coupled to the current input terminal and the current output terminal of the current mirror circuit 100, the equivalent capacitance of the capacitor CA can be effectively increased, thereby saving the capacitor area required for designing the dominant pole at a specific frequency. Thus, the capacitor connection of the present invention can be applied to various amplifier architectures with built-in current mirror circuit(s), such as a telescopic cascode amplifier with built-in current mirror circuit(s), a folded cascode amplifier with built-in current mirror circuit(s) and a current mirror amplifier.

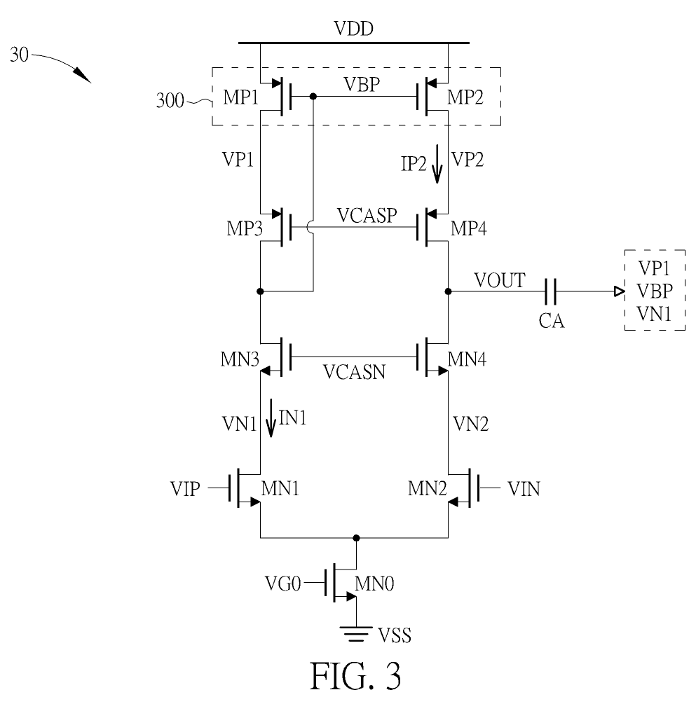

FIG. 3 is a diagram illustrating an operational amplifier 30 with a built-in capacitor multiplier (e.g. a telescopic cascode amplifier with a built-in capacitor multiplier) according to an embodiment of the present invention. As shown in FIG. 3, the operational amplifier 30 may comprise at least one input transistor such as the N-type transistors MN1 and MN2, at least one current mirror circuit such as a current mirror circuit 300, the capacitor CA and a current source such as the N-type transistor MN0. In this embodiment, the N-type transistors MN1 and MN2 may generate an input current according to the input signals on the nodes VIP and VIN (e.g. the N-type transistor MN1 generates the current IN1 according to the input signal on the node VIP), and the current mirror circuit 300 may generate a current mirror output current on a current output terminal of the current mirror circuit 300 according to a current mirror input current received by a current input terminal of the current mirror circuit 300, where the current mirror input current corresponds to the input current (e.g. the current mirror input current is equal to the current IN1), and the current output terminal of the current mirror circuit 300 is coupled to an amplifier output terminal of the operational amplifier 30 (e.g. the node VOUT). In addition, the first terminal of the capacitor CA is coupled to the amplifier output terminal of the operational amplifier 30 such as the node VOUT, and the second terminal of the capacitor CA is coupled to the current input terminal of the current mirror circuit 300, to make the equivalent capacitance of the capacitor CA on the amplifier output terminal of the operational amplifier 30 (e.g. the equivalent capacitance on the node VOUT) be multiplied by the current mirror circuit 300.

In addition, as connection between the current source (e.g. the N-type transistor MN0) and the input transistors (e.g. the N-type transistors MN1 and MN2) and associated operations thereof are the same as in the embodiment of FIG. 1, related details are omitted here for brevity. In this embodiment, the current mirror circuit 300 may comprise a first current mirror transistor such as the P-type transistor MP1 and a second current mirror transistor such as the P-type transistor MP2, where the source terminals of the P-type transistors MP1 and MP2 are both coupled to the reference voltage VDD, the gate terminal of the P-type transistor MP1 is coupled to the drain terminal of the P-type transistor MP1 via MP3 in order to generate the control voltage on the gate terminal of the P-type transistor MP1 (e.g. the voltage on the node VBP) according to the current mirror input current (e.g. the current IN1 received by the drain terminal of the P-type transistor MP1), and the gate terminal of the P-type transistor MP2 is coupled to the gate terminal of the P-type transistor MP1 (as shown by the node VBP) in order to generate the current mirror output current (e.g. the current IP2) according to the control voltage. More particularly, the drain terminal of the P-type transistor MP1 may represent the current input terminal of the current mirror circuit 300, and the drain terminal of the P-type transistor MP2 may represent the current output terminal of the current mirror circuit 300.

In comparison with the operational amplifier 10 shown in FIG. 1, the operational amplifier 30 shown in FIG. 3 may further comprise a first cascode transistor such as a P-type transistor MP3, a second cascode transistor such as an N-type transistor MN3, a third cascode transistor such as a P-type transistor MP4, and a fourth cascode transistor such as an N-type transistor MN4. As shown in FIG. 3, a source terminal of the P-type transistor MP3 is coupled to the drain terminal of the P-type transistor MP1 (as shown by a node VP1), and the drain terminal of the P-type transistor MP3 is coupled to the gate terminal of the P-type transistor MP1 (as shown by the node VBP), to make the gate terminal of the P-type transistor MP1 be coupled to the drain terminal of the P-type transistor MP1 via the P-type transistor MP3. A source terminal of the N-type transistor MN3 is coupled to the drain terminal of the N-type transistor MN1 (as shown by a node VN1), and a drain terminal of the N-type transistor MN3 is coupled to the drain terminal of the P-type transistor MP3 (as shown by the node VBP). A source terminal of the P-type transistor MP4 is coupled to the drain terminal of the P-type transistor MP2 (as shown by a node VP2), and a drain terminal of the P-type transistor MP4 is the amplifier output terminal of the operational amplifier 30 (as shown by the node VOUT). A source terminal of the N-type transistor MN4 is coupled to the drain terminal of the N-type transistor MN2 (as shown by a node VN2), and a drain terminal of the N-type transistor MN4 is coupled to the drain terminal of the P-type transistor MP4 (as shown by the node VOUT). A voltage on the gate terminal of the N-type transistor MN0 (e.g. a voltage on the node VG0), voltages on gate terminals of the N-type transistors MN3 and MN4 (e.g. a voltage on the node VCASN) and voltages on the P-type transistors MP3 and MP4 (e.g. a voltage on the node VCASP) are controlled by a bias voltage generating circuit (not shown in figures), where implementation of this bias voltage generating circuit should be well known by those skilled in this art, and related details are omitted here for brevity.

In this embodiment, the first terminal of the capacitor CA is coupled to the amplifier output terminal of the operational amplifier 30 (as shown by the node VOUT), and the second terminal of the capacitor CA is coupled to any node on a current path to which the current input terminal of the current mirror circuit 300 belongs. For example, the second terminal of the capacitor CA may be coupled (e.g. directly connected) to the drain terminal of the P-type transistor MP1 (e.g. the node VP1). In another example, the second terminal of the capacitor CA may be coupled (e.g. directly connected) to the drain terminal of the P-type transistor MP3 (e.g. the node VBP), in order to be coupled to the current input terminal of the current mirror circuit 300 (e.g. the node VP1) via the P-type transistor MP3. In another example, the second terminal of the capacitor CA may be coupled (e.g. directly connected) to the source terminal of the N-type transistor MN3 (e.g. the node VN1), in order to be coupled to the current input terminal of the current mirror circuit 300 (e.g. the node VP1) via the P-type transistor MP3 and the N-type transistor MN3. In this embodiment, as the P-type transistor MP1 and MP2 within the current mirror circuit 300 are typically designed to have the same size, the equivalent capacitance of the capacitor CA on the amplifier output terminal of the operational amplifier 30 (e.g. the equivalent capacitance on the node VOUT) may be twice the capacitance of the capacitor CA.

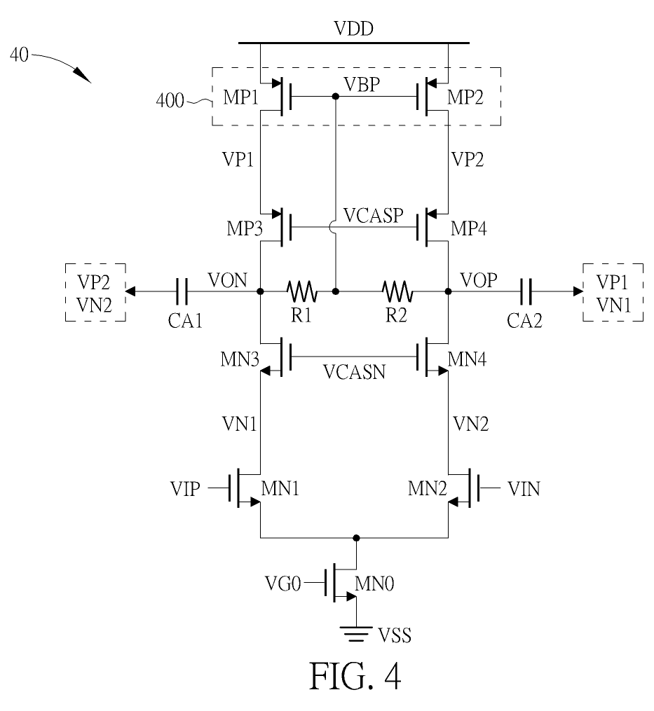

It should be noted that the operational amplifier 30 shown in FIG. 3 is a differential input with single-ended output architecture, but the present invention is not limited thereto. FIG. 4 is a diagram illustrating a fully-differential architecture (e.g. a differential input with differential output architecture) which is modified based on the operational amplifier 30 shown in FIG. 3 according to an embodiment of the present invention, such as an operational amplifier 40 with a built-in capacitor multiplier. In comparison with the operational amplifier 30 shown in FIG. 3, the drain terminal of the P-type transistor MP4 and the drain terminal of the P-type transistor MP3 within the operational amplifier 40 shown in FIG. 4 are a first amplifier output terminal (as shown by a node VOP) and a second amplifier output terminal (as shown by a node VON) of the operational amplifier 40, respectively. A difference between a current mirror circuit 400 within the operational amplifier 40 and the current mirror circuit 300 within the operational amplifier 30 is that the drain terminal of the P-type transistor MP3 (e.g. the node VON) is coupled to the gate terminal of the P-type transistor MP1 within the current mirror circuit 400 via a resistor R1 (as shown by the node VBP), and the drain terminal of the P-type transistor MP4 (e.g. the node VOP) is coupled to the gate terminal of the P-type transistor MP2 within the current mirror circuit 400 via the resistor R2 (as shown by the node VBP). In addition, the operational amplifier 40 may comprise capacitors CA1 and CA2, where a first terminal of the capacitor CA1 is coupled to the second amplifier output terminal of the operational amplifier 40 (e.g. the node VON), and a first terminal of the capacitor CA2 is coupled to the first amplifier output terminal of the operational amplifier 40 (e.g. the node VOP). In addition, a second terminal of the capacitor CA1 is coupled to any node (other the node VON) on a current path to which the drain terminal of the P-type transistor MP2 belongs, and a second terminal of the capacitor CA2 is coupled to any node (other than the node VON) on a current path to which the drain terminal of the P-type transistor MP1 belongs. For example, the second terminal of the capacitor CA1 is coupled (e.g. directly connected) to the drain terminal of the P-type transistor MP2 (e.g. the node VP2), and the second terminal of the capacitor CA2 is coupled (e.g. directly connected) to the drain terminal of the P-type transistor MP1 (e.g. the node VP1). In another example, the second terminal of the capacitor CA1 is coupled (e.g. directly connected) to the source terminal of the N-type transistor MN4 (e.g. the node VN2), in order to be coupled to the drain terminal of the P-type transistor MP2 via the P-type transistor MP4 and the N-type transistor MN4, and the second terminal of the capacitor CA2 is coupled (e.g. directly connected) to the source terminal of the N-type transistor MN3 (e.g. the node VN1), in order to be coupled to the drain terminal of the P-type transistor MP1 via the P-type transistor MP3 and the N-type transistor MN3. In this embodiment, as the P-type transistors MP1 and MP2 within the current mirror circuit 400 are typically designed to have the same size, the equivalent capacitance of the capacitor CA1 on the second amplifier output terminal of the operational amplifier 40 (e.g. the equivalent capacitance on the node VON) may be twice the capacitance of the capacitor CA1, and the equivalent capacitance of the capacitor CA2 on the first amplifier output terminal of the operational amplifier 40 (e.g. the equivalent capacitance on the node VOP) may be twice the capacitance of the capacitor CA2.

Those skilled in this art should understand how to modify the architecture of the operational amplifier 30 to implement the operational amplifier 40 according to the difference between the architectures shown in FIG. 3 and FIG. 4, and related detail is omitted here for brevity.

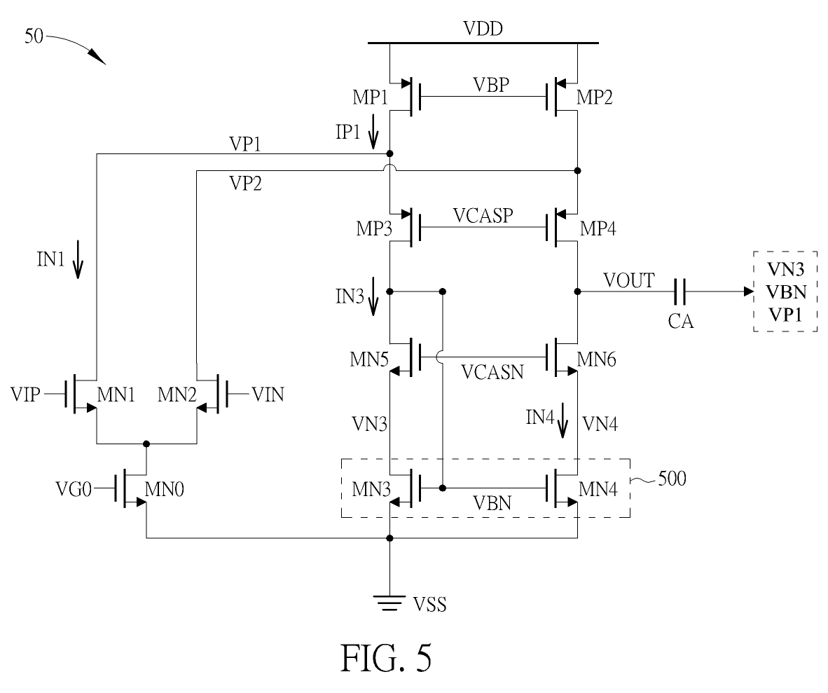

FIG. 5 is a diagram illustrating an operational amplifier 50 with a built-in capacitor multiplier (e.g. a folded cascode operational amplifier with a built-in capacitor multiplier) according to an embodiment of the present invention. As shown in FIG. 5, the operational amplifier 50 may comprise at least one input transistor such as the N-type transistors MN1 and MN2, at least one current mirror circuit such as a current mirror circuit 500, the capacitor CA and multiple current sources such as the N-type transistor MN0, the P-type transistors MP1 and MP2. The connection between the current source (e.g. the N-type transistor MN0) and the input transistors (e.g. the N-type transistor MN1 and MN2) and associated operations thereof are the same as in the embodiment of FIG. 1, and related details are omitted here for brevity. In addition, the source terminals of the P-type transistors MP1 and MP2 are both coupled to the reference voltage VDD, where the drain terminal of the P-type transistor MP1 is coupled to the drain terminal of the N-type transistor MN1, and the drain terminal of the P-type transistor MP2 is coupled to the drain terminal of the N-type transistor MN2. In this embodiment, the N-type transistors MN1 and MN2 may generate an input current according to the input signals on the nodes VIP and VIN (e.g. the N-type transistor MN1 generates the current IN1 according to the input signal on the node VIP), and the current mirror circuit 500 may generate a current mirror output current (e.g. a current IN4) on a current output terminal of the current mirror circuit 500 according to a current mirror input current (e.g. the current IN3) received by a current input terminal of the current mirror circuit 500, where the current mirror input current corresponds to the input current (e.g. IN3 = IP1 - IN1, where IP1 is a current generated by the P-type transistor MP1 according to a voltage on the gate terminal of the P-type transistor MP1 such as the node VBP), and the current output terminal of the current mirror circuit 500 is coupled to an amplifier output terminal of the operational amplifier 50 (e.g. the node VOUT) via MN6. In addition, the first terminal of the capacitor CA is coupled to the amplifier output terminal of the operational amplifier 50 such as the node VOUT, and the second terminal of the capacitor CA is coupled to the current input terminal of the current mirror circuit 500, to make the equivalent capacitance of the capacitor CA on the amplifier output terminal of the operational amplifier 50 (e.g. the equivalent capacitance on the node VOUT) is multiplied by the current mirror circuit 500.

In this embodiment, the current mirror circuit 500 may comprise a first current mirror transistor such as the N-type transistor MN3 and a second current mirror transistor such as the N-type transistor MN4, where the source terminals of the N-type transistors MN3 and MN4 are both coupled to the reference voltage VSS, and a gate terminal of the N-type transistor MN3 is coupled to the drain terminal of the N-type transistor MN3 via MN5 in order to generate a control voltage on the gate terminal of the N-type transistor MN3 (e.g. a voltage on the node VBN) according to the current mirror input current (e.g. the current IN3 received by the drain terminal of the N-type transistor MN3), and a gate terminal of the N-type transistor MN4 is coupled to the gate terminal of the N-type transistor MN3 (as shown by the node VBN) in order to generate the current mirror output current (e.g. the current IN4) according to the control voltage. More particularly, the drain terminal of the N-type transistor MN3 may represent the current input terminal of the current mirror circuit 500, and the drain terminal of the N-type transistor MN4 may represent the current output terminal of the current mirror circuit 500.

In this embodiment, the operational amplifier 50 may further comprise a first cascode transistor such as an N-type transistor MN5, a second cascode transistor such as the P-type transistor MP3, a third cascode transistor such as an N-type transistor MN6, and a fourth cascode transistor such as the P-type transistor MP4. As shown in FIG. 5, a source terminal of the N-type transistor MN5 is coupled to the drain terminal of the N-type transistor MN3 (as shown by a node VN3), and a drain terminal of the N-type transistor MN5 is coupled to the gate terminal of the N-type transistor MN3 (as shown by the node VBN), to make the gate terminal of the N-type transistor MN3 be coupled to the drain terminal of the N-type transistor MN3 via the N-type transistor MN5. The source terminal of the P-type transistor MP3 is coupled to the drain terminal of the N-type transistor MN1 and the drain terminal of the P-type transistor MP1 (as shown by the node VP1), and the drain terminal of the P-type transistor MP3 is coupled to the drain terminal of the N-type transistor MN5 (as shown by the node VBN). A source terminal of the N-type transistor MN6 is coupled to the drain terminal of the N-type transistor MN4 (as shown by a node VN4), and a drain terminal of the N-type transistor MN6 is the amplifier output terminal of the operational amplifier 50 (as shown by the node VOUT). The source terminal of the P-type transistor MP4 is coupled to the drain terminal of the N-type transistor MN2 and the drain terminal of the P-type transistor MP2 (as shown by the node VP2), and the drain terminal of the P-type transistor MP4 is coupled to the drain terminal of the N-type transistor MN6 (as shown by the node VOUT). The voltage on the gate terminal of the N-type transistor MN0 (e.g. the voltage on the node VG0), the voltages on the gate terminals of the P-type transistors MP1 and MP2 (e.g. the voltage on the node VBP), the voltages on the gate terminals of the P-type transistors MP3 and MP4 (e.g. the voltage on the node VCASP) and the voltages on the gate terminals of the N-type transistors MN5 and MN6 (e.g. the voltage on the node VCASN) is controlled by a bias voltage generating circuit (not shown in figures), where implementation of this bias voltage generating circuit should be well known by those skilled in this art, and related details are omitted here for brevity.

In this embodiment, the first terminal of the capacitor CA is coupled to the amplifier output terminal of the operational amplifier 50 (as shown by the node VOUT), and the second terminal of the capacitor CA is coupled to any node on a current path to which the current input terminal of the current mirror circuit 500 belongs. For example, the second terminal of the capacitor CA may be coupled (e.g. directly connected) to the source terminal of the N-type transistor MN5 (e.g. the node VN3). In another example, the second terminal of the capacitor CA may be coupled (e.g. directly connected) to the drain terminal of the P-type transistor MP3 (e.g. the node VBN) in order to be coupled to the current input terminal of the current mirror circuit 500 (e.g. the node VN3) via the N-type transistor MN5. In another example, the second terminal of the capacitor CA may be coupled (e.g. directly connected) to the drain terminal of the P-type transistor MP1 (e.g. the node VP1) in order to be coupled to the current input terminal of the current mirror circuit 500 (e.g. the node VN3) via the P-type transistor MP3 and the N-type transistor MN5. In this embodiment, as the N-type transistor MN3 and MN4 within the current mirror circuit 500 are typically designed to have the same size, the equivalent capacitance of the capacitor CA on the amplifier output terminal of the operational amplifier 50 (e.g. the equivalent capacitance on the node VOUT) may be twice the capacitance of the capacitor CA.

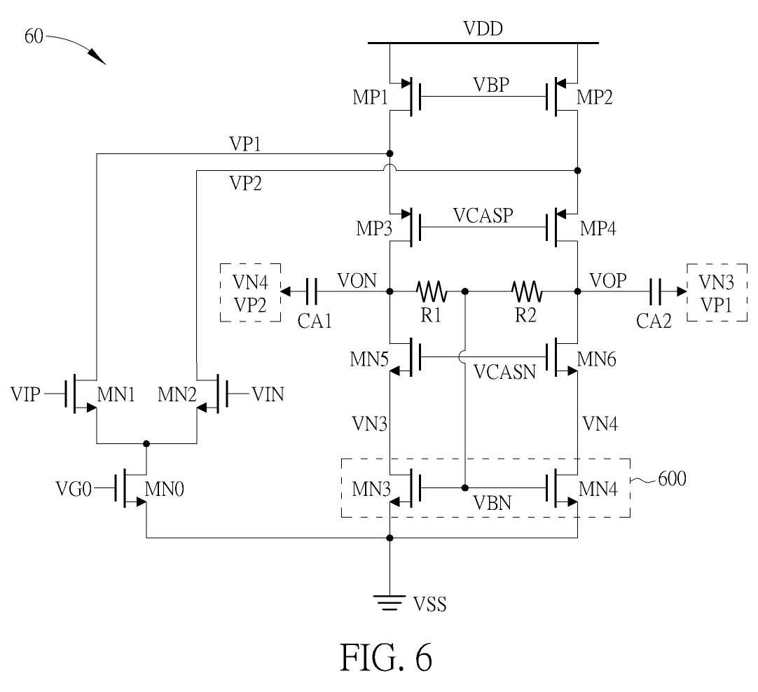

It should be noted that the operational amplifier 50 shown in FIG. 5 has a differential input with single-ended output architecture, but the present invention is not limited thereto. FIG. 6 is a diagram illustrating a fully-differential architecture (e.g. a differential input with differential output architecture) which is modified based on the operational amplifier 50 shown in FIG. 5 according to an embodiment of the present invention, such as an operational amplifier 60 with a built-in capacitor multiplier. In comparison with the operational amplifier 50 shown in FIG. 5, the drain terminal of the N-type transistor MN6 and the drain terminal of the N-type transistor MN5 of the operational amplifier 60 shown in FIG. 6 are a first amplifier output terminal (as shown by the node VOP) and a second amplifier output terminal (as shown by the node VON) of the operational amplifier 60, respectively. A difference between a current mirror circuit 600 within the operational amplifier 60 and the current mirror circuit 500 within the operational amplifier 50 is that the drain terminal of the N-type transistor MN5 (e.g. the node VON) is coupled to the gate terminal of the N-type transistor MN3 within the current mirror circuit 600 via the resistor R1 (as shown by the node VBN), and the drain terminal of the N-type transistor MN6 (e.g. the node VOP) is coupled to the gate terminal of the N-type transistor MN4 within the current mirror circuit 600 via the resistor R2 (as shown by the node VBN). In addition, the operational amplifier 60 may comprise the capacitors CA1 and CA2, where the first terminal of the capacitor CA1 is coupled to the second amplifier output terminal (e.g. the node VON) of the operational amplifier 60, and the first terminal of the capacitor CA2 is coupled to the first amplifier output terminal (e.g. the node VOP) of the operational amplifier 60. In addition, the second terminal of the capacitor CA1 is coupled to any node (other than the node VOP) on a current path to which the drain terminal of the N-type transistor MN4 belongs, and the second terminal of the capacitor CA2 is coupled to any node (other than the node VON) on a current path to which the drain terminal of the N-type transistor MN3 belongs. For example, the second terminal of the capacitor CA1 is coupled (e.g. directly connected) to the drain terminal of the N-type transistor MN4 (e.g. the node VN4), and the second terminal of the capacitor CA2 is coupled (e.g. directly connected) to the drain terminal of the N-type transistor MN3 (e.g. the node VN3). In another example, the second terminal of the capacitor CA1 is coupled (e.g. directly connected) to the source terminal of the P-type transistor MP4 (e.g. the node VP2) in order to be coupled to the drain terminal of the N-type transistor MN4 via the P-type transistor MP4 and the N-type transistor MN6, and the second terminal of the capacitor CA2 is coupled (e.g. directly connected) to the source terminal of the P-type transistor MP3 (e.g. the node VP1) in order to be coupled to the drain terminal of the N-type transistor MN3 via the P-type transistor MP3 and the N-type transistor MN5. In this embodiment, as the N-type transistor MN3 and MN4 within the current mirror circuit 600 are typically designed to have the same size, the equivalent capacitance of the capacitor CA1 on the second amplifier output terminal of the operational amplifier 60 (e.g. the equivalent capacitance on the node VON) may be twice the capacitance of the capacitor CA1, and the equivalent capacitance of the capacitor CA2 on the first amplifier output terminal of the operational amplifier 60 (e.g. the equivalent capacitance on the node VOP) may be twice the capacitance of the capacitor CA2.

Those skilled in this art should understand how to modify the architecture of the operational amplifier 50 to implement the operational amplifier 60 according to the difference between the architectures shown in FIG. 5 and FIG. 6, and related detail is omitted here for brevity.

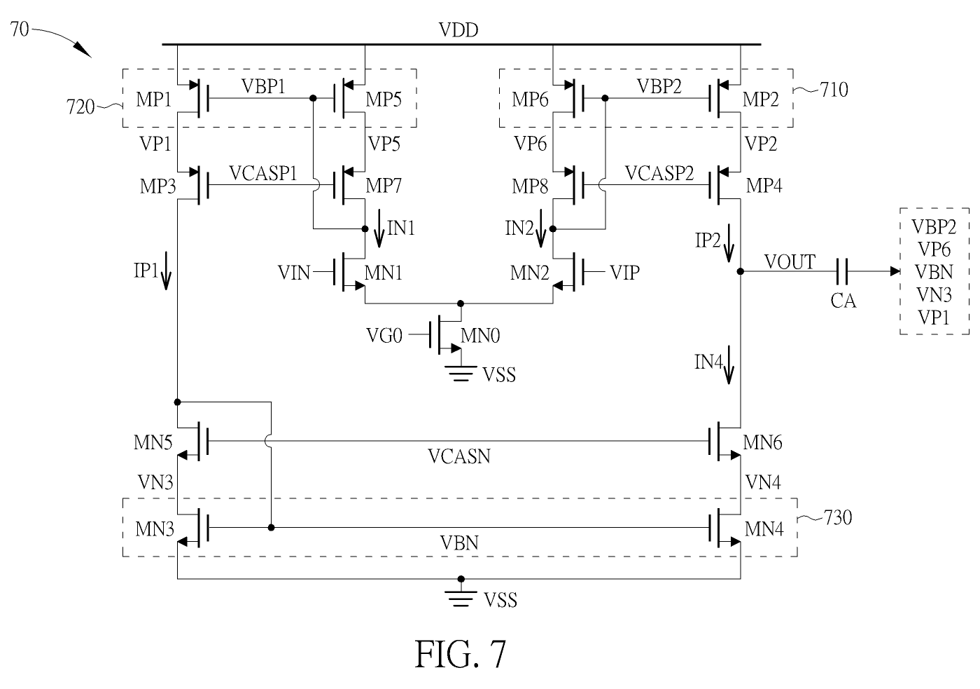

FIG. 7 is a diagram illustrating an operational amplifier 70 with a built-in capacitor multiplier (e.g. a current mirror amplifier with a capacitor multiplier) according to an embodiment of the present invention. As shown in FIG. 7, the operational amplifier 70 may comprise at least one input transistor such as the N-type transistors MN1 and MN2, at least one current mirror circuit such as current mirror circuits 710, 720 and 730, the capacitors CA and a current source such as the N-type transistor MN0. The connection between the current source (e.g. the N-type transistor MN0) and the input transistors (e.g. the N-type transistors MN1 and MN2) and associated operations thereof are the same as in the embodiment of FIG. 1, and related details are omitted here for brevity. In this embodiment, the N-type transistors MN1 and MN2 may generate an input current according to the input signals on the nodes VIN and VIP. For example, the N-type transistor MN1 is configured to generate a first input current such as the current IN1 according to a first input signal such as the input signal on the node VIN, and the N-type transistor MN2 is configured to generate a second input current such as the current IN2 according to a second input signal such as the input signal on the node VIP. The current mirror circuit 710 is configured to generate a first current mirror output current on a current output terminal of the current mirror circuit 710 according to a first current mirror input current received by a current input terminal of the current mirror circuit 710, where the first current mirror input current corresponds to the second input current (e.g. the first current mirror input current is equal to the current IN2), and the current output terminal of the current mirror circuit 710 is coupled to an amplifier output terminal of the operational amplifier 70 via MP4. The current mirror circuit 720 is configured to generate a second current mirror output current on a current output terminal of the current mirror circuit 720 according to a second current mirror input current received by a current input terminal of the current mirror circuit 720, where the second current mirror input current corresponds to the first input current (e.g. the second current mirror input current is equal to the current IN1). The current mirror circuit 730 is configured to generate a third current mirror output current on a current output terminal of the current mirror circuit 730 according to a third current mirror input current received by a current input terminal of the current mirror circuit 730, where the third current mirror input current corresponds to the second current mirror output current (e.g. the third current mirror input current is equal to the second current mirror output current such as IP1), the current input terminal of the current mirror circuit 730 is coupled to the current output terminal of the current mirror circuit 720 via the N-type transistor MN5 and the P-type transistor MP3, and the current output terminal of the current mirror circuit 730 is coupled to the amplifier output terminal of the operational amplifier 70 via the N-type transistor MN6. In addition, the first terminal of the capacitor CA is coupled to the amplifier output terminal of the operational amplifier 70 such as the node VOUT, and the second terminal of the capacitor CA is coupled to the current input terminal of the current mirror circuit 710 or the current input terminal of the current mirror circuit 730, to make the equivalent capacitance of the capacitor CA on the amplifier output terminal of the operational amplifier 70 (e.g. the equivalent capacitance on the node VOUT) be multiplied by the current mirror circuit 710 or 730.

In this embodiment, the current mirror circuit 710 may comprise a first current mirror transistor such as a P-type transistor MP6 and a second current mirror transistor such as the P-type transistor MP2, and the operational amplifier 70 may further comprise a first cascode transistor such as a P-type transistor MP8 and a second cascode transistor such as the P-type transistor MP4. As shown in FIG. 7, source terminals of the P-type transistors MP6 and MP2 are both coupled to the reference voltage VDD. A source terminal of the P-type transistor MP8 is coupled to a drain terminal of the P-type transistor MP6 (as shown by a node VP6), and a drain terminal of the P-type transistor MP8 is coupled to a gate terminal of the P-type transistor MP6 (as shown by a node VBP2), to make the P-type transistor MP6 generate a first control voltage on the gate terminal of the P-type transistor MP6 (e.g. a voltage on the node VBP2) according to the first current mirror input current (e.g. the current IN2), where the P-type transistor MP2 may generate the first current mirror output current (e.g. the current IP2) according to the first control voltage. The source terminal of the P-type transistor MP4 is coupled to the drain terminal of the P-type transistor MP2 (as shown by the node VP2), and the drain terminal of the P-type transistor MP4 is the amplifier output terminal of the operational amplifier 70 (as shown by the node VOUT). More particularly, the drain terminal of the P-type transistor MP6 (e.g. the node VP6) may represent the current input terminal of the current mirror circuit 710, and the drain terminal of the P-type transistor MP2 (e.g. the node VP2) may represent the current output terminal of the current mirror circuit 710, where the second terminal of the capacitor CA may be coupled to any node on a path to which the current input terminal of the current mirror circuit 710 belongs. For example, the second terminal of the capacitor CA is coupled (e.g. directly connected) to the drain terminal of the P-type transistor MP6 (e.g. the node VP6). In another example, the second terminal of the capacitor CA is coupled (e.g. directly connected) to the drain terminal of the P-type transistor MP8 (e.g. the node VBP2), in order to be coupled to the current input terminal of the current mirror circuit 710 via the P-type transistor MP8. When the current mirror circuit 710 is designed to scale the current N times (which means the size of the P-type transistor MP2 is N times the size of the P-type transistor MP6), configuring the second terminal of the capacitor CA to be coupled to any node (e.g. the node VP6 or VBP2) on a current path to which the drain terminal of the P-type transistor MP6 belongs can make the equivalent capacitance of the capacitor CA on the amplifier output terminal of the operational amplifier 70 (e.g. the equivalent capacitance on the node VOUT) be (1+N) times the capacitance of the capacitor CA.

In this embodiment, the current mirror circuit 720 may comprise a first current mirror transistor such as a P-type transistor MP5 and a second current mirror transistor such as the P-type transistor MP1, and the current mirror circuit 730 may comprise a third current mirror transistor such as the N-type transistor MN3 and a fourth current mirror transistor such as the N-type transistor MN4. In addition, the operational amplifier 70 may further comprise a first cascode transistor such as a P-type transistor MP7, a second cascode transistor such as the P-type transistor MP3, a third cascode transistor such as the N-type transistor MN5 and a fourth cascode transistor such as the N-type transistor MN6. As shown in FIG. 7, source terminals of the P-type transistors MP5 and MP1 are both coupled to the reference voltage VDD, and the source terminals of the N-type transistors MN3 and MN4 are both coupled to the reference voltage VSS. A source terminal of the P-type transistor MP7 is coupled to the drain terminal of the P-type transistor MP5 (as shown by a node VP5), and a drain terminal of the P-type transistor MP7 coupled to a gate terminal of the P-type transistor MP5 (as shown by a node VBP1), to make the P-type transistor MP5 generate a second control voltage on the gate terminal of the P-type transistor MP5 (e.g. a voltage on the node VBP1) according to the second current mirror input current (e.g. the current IN1), where the P-type transistor MP1 may generate the second current mirror output current (e.g. the current IP1) the second control voltage. The source terminal of the P-type transistor MP3 is coupled to the drain terminal of the P-type transistor MP1 (as shown by the node VP1). The source terminal of the N-type transistor MN5 is coupled to the drain terminal of the N-type transistor MN3 (as shown by the node VN3), and the drain terminal of the N-type transistor MN5 is coupled to the gate terminal of the N-type transistor MN3 (as shown by the node VBN) and the drain terminal of the P-type transistor MP3, to make the N-type transistor MN3 generate a third control voltage on the gate terminal of the N-type transistor MN3 (e.g. the voltage on the node VBN) according to the third current mirror input current (e.g. the current IP1), where the N-type transistor MN4 generates the third current mirror output current (e.g. the current IN4) according to the third control voltage. The source terminal of the N-type transistor MN6 is coupled to the drain terminal of the N-type transistor MN4 (as shown by the node VN4), and the drain terminal of the N-type transistor MN6 is the amplifier output terminal of the operational amplifier 70 (as shown by the node VOUT). More particularly, the drain terminal of the P-type transistor MP5 (e.g. the node VP5) may represent the current input terminal of the current mirror circuit 720, the drain terminal of the P-type transistor MP1 (e.g. the node VP1) may represent the current output terminal of the current mirror circuit 720, the drain terminal of the N-type transistor MN3 (e.g. the node VN3) may represent the current input terminal of the current mirror circuit 730, and the drain terminal of the N-type transistor MN4 (e.g. the node VN4) may represent the current output terminal of the current mirror circuit 730, where the second terminal of the capacitor CA may be coupled to any node on a current path to which the current input terminal of the current mirror circuit 730 belongs. For example, the second terminal of the capacitor CA is coupled (e.g. directly connected) to the drain terminal of the N-type transistor MN3 (e.g. the node VN3). In another example, the second terminal of the capacitor CA is coupled (e.g. directly connected) to the drain terminal of the P-type transistor MP3 (e.g. the node VBN), in order to be coupled to the current input terminal of the current mirror circuit 730 via the N-type transistor MN5. In another example, the second terminal of the capacitor CA is coupled (e.g. directly connected) to the drain terminal of the P-type transistor MP1 (e.g. the node VP1), in order to be coupled to the current input terminal of the current mirror circuit 730 via the P-type transistor MP3 and the N-type transistor MN5. When the current mirror circuit 710 is designed to scale the current N times (which means the size of the P-type transistor MP2 is N times the size of the P-type transistor MP6) and the current mirror circuit 720 is designed to scale the current M times (which means the size of the P-type transistor MP1 is M times the size of the P-type transistor MP5), the current mirror circuit 730 needs to be designed to scale the current N/M times, where configuring the second terminal of the capacitor CA to be coupled to any node (e.g. the nodes VN3, VBN or VP1) on a current path to which the drain terminal of the N-type transistor MN3 belongs can make the equivalent capacitance of the capacitor CA on the amplifier output terminal of the operational amplifier 70 (e.g. the equivalent capacitance on the node VOUT) be (1+N/M) times the capacitance of the capacitor CA.

In this embodiment, the voltage on the gate terminal of the N-type transistor MN0 (e.g. the voltage on the node VG0), voltages on gate terminals of the P-type transistors MP3 and MP7 (e.g. a voltage on a node VCASP1), voltages on gate terminals of the P-type transistors MP4 and MP8 (e.g. a voltage on a node VCASP2), and voltages on gate terminals of the N-type transistors MN5 and MN6 (e.g. the voltage on the node VCASN) are controlled by a bias voltage generating circuit (not shown in figures), where implementation of this bias voltage generating circuit should be well known by those skilled in this art, and related details are omitted here for brevity.

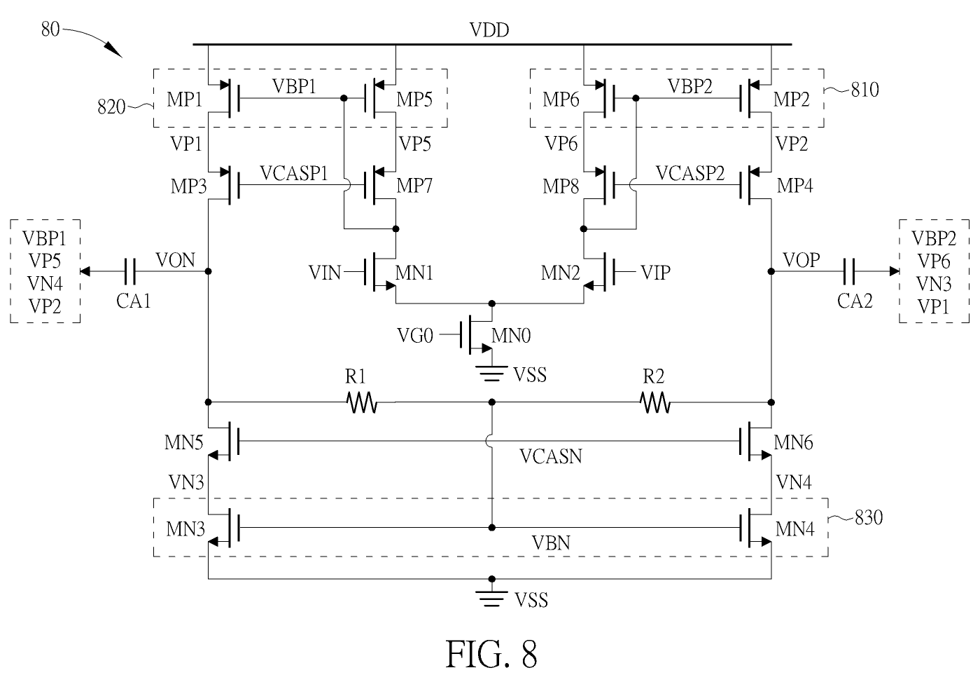

It should be noted that the operational amplifier 70 shown in FIG. 7 has a differential input with single-ended output architecture, but the present invention is not limited thereto. FIG. 8 is a diagram illustrating a fully-differential architecture (e.g. a differential input with differential output architecture) which is modified based on the operational amplifier 70 shown in FIG. 7 according to an embodiment of the present invention, such as an operational amplifier 80 with a built-in capacitor multiplier. In comparison with the operational amplifier 70 shown in FIG. 7, the drain terminal of the N-type transistor MN6 and the drain terminal of the N-type transistor MN5 within the operational amplifier 80 shown in FIG. 8 are a first amplifier output terminal (as shown by the node VOP) and a second amplifier output terminal (as shown by the node VON) of the operational amplifier 80, respectively. Current mirror circuits 810 and 820 within the operational amplifier 80 are the same as the current mirror circuits 710 and 720 within the operational amplifier 70, where a difference between a current mirror circuit 830 within the operational amplifier 80 and the current mirror circuit 730 within the operational amplifier 70 is that the drain terminal of the N-type transistor MN5 (e.g. the node VON) is coupled to the gate terminal of the N-type transistor MN3 within the current mirror circuit 830 via the resistor R1 (as shown by the node VBN), and the drain terminal of the N-type transistor MN6 (e.g. the node VOP) is coupled to the gate terminal of the N-type transistor MN4 within the current mirror circuit 830 via the resistor R2 (as shown by the node VBN). In addition, the operational amplifier 80 may comprise the capacitors CA1 and CA2, where the first terminal of the capacitor CA1 is coupled to the second amplifier output terminal (e.g. the node VON) of the operational amplifier 80, and the first terminal of the capacitor CA2 is coupled to the first amplifier output terminal (e.g. the node VOP) of the operational amplifier 80.

In some embodiments, the second terminal of the capacitor CA1 is coupled to any node on a current path to which the drain terminal of the P-type transistor MP5 belongs, and the second terminal of the capacitor CA2 is coupled to any node on a current path to which the drain terminal of the P-type transistor MP6 belongs. For example, the second terminal of the capacitor CA1 is coupled (e.g. directly connected) to the drain terminal of the P-type transistor MP5 (e.g. the node VP5), and the second terminal of the capacitor CA2 is coupled (e.g. directly connected) to the drain terminal of the P-type transistor MP6 (e.g. the node VP6). In another example, the second terminal of the capacitor CA1 is coupled (e.g. directly connected) to the drain terminal of the P-type transistor MP7 (e.g. the node VBP1), in order to be coupled to the drain terminal of the P-type transistor MP5 via the P-type transistor MP7, and the second terminal of the capacitor CA2 is coupled (e.g. directly connected) to the drain terminal of the P-type transistor MP8 (e.g. the node VBP2), in order to be coupled to the drain terminal of the P-type transistor MP6 via the P-type transistor MP8. It should be noted that the current mirror circuits 810 and 820 are typically designed to have the same current scaling ratio. When the current mirror circuits 810 and 820 are designed to scale the current N times (which means the size of the P-type transistor MP2 is N times the size of the P-type transistor MP6 and the size of the P-type transistor MP1 is N times the size of the P-type transistor MP5), configuring the second terminal of the capacitor CA1 to be coupled to any node (e.g. the node VP5 or VBP1) on a current path to which the drain terminal of the P-type transistor MP5 belongs and configuring the second terminal of the capacitor CA2 to be coupled to any node (e.g. the node VP6 or VBP2) on a current path to which the drain terminal of the P-type transistor MP6 belongs can make the equivalent capacitance of the capacitor CA1 on the second amplifier output terminal of the operational amplifier 80 (e.g. the equivalent capacitance on the node VON) be (1+N) times the capacitance of the capacitor CA1 and make the equivalent capacitance of the capacitor CA2 on the first amplifier output terminal of the operational amplifier 80 (e.g. the equivalent capacitance on the node VOP) be (1+N) times the capacitance of the capacitor CA2.

In some embodiments, the second terminal of the capacitor CA1 is coupled to any node (other than the node VOP) on a current path to which the drain terminal of the N-type transistor MN4 belongs, and the second terminal of the capacitor CA2 is coupled to any node (other than the node VON) on a current path to which the drain terminal of the N-type transistor MN3 belongs. For example, the second terminal of the capacitor CA1 is coupled (e.g. directly connected) to the drain terminal of the N-type transistor MN4 (e.g. the node VN4), and the second terminal of the capacitor CA2 is coupled (e.g. directly connected) to the drain terminal of the N-type transistor MN3 (e.g. the node VN3). In another example, the second terminal of the capacitor CA1 is coupled (e.g. directly connected) to the source terminal of the P-type transistor MP4 (e.g. the node VP2) in order to be coupled to the drain terminal of the N-type transistor MN4 via the P-type transistor MP4 and the N-type transistor MN6, and the second terminal of the capacitor CA2 is coupled (e.g. directly connected) to the source terminal of the P-type transistor MP3 (e.g. the node VP1) in order to be coupled to the drain terminal of the N-type transistor MN3 via the P-type transistor MP3 and the N-type transistor MN5. In addition, as the N-type transistor MN3 and MN4 within the current mirror circuit 830 are typically designed to have the same size, configuring the second terminal of the capacitor CA1 to be coupled to any node other than the node VOP (e.g. the node VN4 or VP2) on the current path to which the drain terminal of the N-type transistor MN4 belongs and configuring the second terminal of the capacitor CA2 to be coupled to any node other than the node VON (e.g. the node VN3 or VP1) on the current path to which the drain terminal of the N-type transistor MN3 belongs can make the equivalent capacitance of the capacitor CA1 on the second amplifier output terminal of the operational amplifier 80 (e.g. the equivalent capacitance on the node VON) be twice the capacitance of the capacitor CA1, and make the equivalent capacitance of the capacitor CA2 on the first amplifier output terminal of the operational amplifier 80 (e.g. the equivalent capacitance on the node VOP) be twice the capacitance of the capacitor CA2.

Those skilled in this art should understand how to modify the architecture of the operational amplifier 70 to implement the operational amplifier 80 according to the difference between the architectures shown in FIG. 7 and FIG. 8, and related detail is omitted here for brevity.

To summarize, the operational amplifiers provided by the embodiments of the present invention configure a capacitor to be coupled across an input and an output of a built-in current mirror circuit, in order to form a built-in capacitor multiplier therein. In addition, the embodiments of the present invention do not need additional circuit(s). Thus, the present invention can push a dominant pole of an operational amplifier toward the low frequency without greatly increasing an overall circuit area and power consumption.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An operational amplifier with a built-in capacitor multiplier, comprising:
at least one input transistor, configured to generate an input current according to an input signal;
at least one current mirror circuit, configured to generate a current mirror output current on a current output terminal of the at least one current mirror circuit according to a current mirror input current received by a current input terminal of the at least one current mirror circuit, wherein the current mirror input current corresponds to the input current, and the current output terminal of the at least one current mirror circuit is coupled to an amplifier output terminal of the operational amplifier; and
a capacitor, wherein a first terminal of the capacitor is coupled to the amplifier output terminal, and a second terminal of the capacitor is coupled to the current input terminal, to make an equivalent capacitance of the capacitor on the amplifier output terminal be multiplied by the current mirror circuit.

2. The operational amplifier of claim 1, wherein the at least one current mirror circuit comprises:
a first current mirror transistor, wherein a gate terminal of the first current mirror transistor is coupled to a drain terminal of the first current mirror transistor, in order to generate a control voltage on the gate terminal of the first current mirror transistor according to the current mirror input current; and
a second current mirror transistor, wherein a gate terminal of the second current mirror transistor is coupled to the gate terminal of the first current mirror transistor, in order to generate the current mirror output current according to the control voltage;
wherein the drain terminal of the first current mirror transistor represents the current input terminal, and a drain terminal of the second current mirror transistor represents the current output terminal.

3. The operational amplifier of claim 2, wherein the at least one input transistor comprises:
a first input transistor, wherein a drain terminal of the first input transistor is coupled to the drain terminal of the first current mirror transistor, and a gate terminal of the first input transistor is configured to receive a first input signal of the input signal; and
a second input transistor, wherein a drain terminal of the second input transistor is coupled to a drain terminal of the second current mirror transistor, and a gate terminal of the second input transistor is configured to receive a second input signal of the input signal;
wherein the drain terminal of the second current mirror transistor is the amplifier output terminal.

4. The operational amplifier of claim 2, further comprising:
a first cascode transistor, wherein a source terminal of the first cascode transistor is coupled to the drain terminal of the first current mirror transistor, and a drain terminal of the first cascode transistor is coupled to the gate terminal of the first current mirror transistor, to make the gate terminal of the first current mirror transistor be coupled to the drain terminal of the first current mirror transistor via the first cascode transistor;
a second cascode transistor, wherein a source terminal of the second cascode transistor is coupled to a drain terminal of the at least one input transistor, and a drain terminal of the second cascode transistor is coupled to the drain terminal of the first cascode transistor; and
a third cascode transistor, wherein a source terminal of the third cascode transistor is coupled to the drain terminal of the second current mirror transistor, and a drain terminal of the third cascode transistor is the amplifier output terminal.

5. The operational amplifier of claim 4, wherein the second terminal of the capacitor is coupled to the drain terminal of the first current mirror transistor.

6. The operational amplifier of claim 4, wherein the second terminal of the capacitor is coupled to the drain terminal of the first cascode transistor in order to be coupled to the current input terminal via the first cascode transistor.

7. The operational amplifier of claim 4, wherein the second terminal of the capacitor is coupled to the source terminal of the second cascode transistor in order to be coupled to the current input terminal via the first cascode transistor and the second cascode transistor.

8. The operational amplifier of claim 1, wherein the at least one input transistor comprises a first input transistor and a second input transistor, the first input transistor is configured to generate a first input current according to a first input signal of the input signal, the second input transistor is configured to generate a second input current according to a second input signal of the input signal, and the at least one current mirror circuit comprises:
a first current mirror circuit, configured to generate a first current mirror output current on a first current output terminal of the first current mirror circuit according to a first current mirror input current received by a first current input terminal of the first current mirror circuit, wherein the first current mirror input current corresponds to the second input current, and the first current output terminal of the first current mirror circuit is coupled to the amplifier output terminal;
a second current mirror circuit, configured to generate a second current mirror output current on a second current output terminal of the second current mirror circuit according to a second current mirror input current received by a second current input terminal of the second current mirror circuit, wherein the second current mirror input current corresponds to the first input current; and
a third current mirror circuit, configured to generate a third current mirror output current on a third current output terminal of the third current mirror circuit according to a third current mirror input current received by a third current input terminal of the third current mirror circuit, wherein the third current mirror input current corresponds to the second current mirror output current, the third current input terminal of the third current mirror circuit is coupled to the second current output terminal of the second current mirror circuit, and the third current output terminal of the third current mirror circuit is coupled to the amplifier output terminal;
wherein the second terminal of the capacitor is coupled to the first current input terminal of the first current mirror circuit, to make the equivalent capacitance of the capacitor on the amplifier output terminal be multiplied by the first current mirror circuit.

9. The operational amplifier of claim 8, wherein the first current mirror circuit comprises a first current mirror transistor and a second current mirror transistor, and the operational amplifier further comprises:
a first cascode transistor, wherein a source terminal of the first cascode transistor is coupled to a drain terminal of the first current mirror transistor, and a drain terminal of the first cascode transistor is coupled to a gate terminal of the first current mirror transistor, to make the first current mirror transistor generate a first control voltage on the gate terminal of the first current mirror transistor according to the first current mirror input current, wherein the second current mirror transistor generates the first current mirror output current according to the first control voltage; and
a second cascode transistor, wherein a source terminal of the second cascode transistor is coupled to a drain terminal of the second current mirror transistor, and a drain terminal of the second cascode transistor is the amplifier output terminal;
wherein the drain terminal of the first current mirror transistor represents the first current input terminal, the drain terminal of the second current mirror transistor represent the first current output terminal, and the second terminal of the capacitor is coupled to the drain terminal of the first current mirror transistor.

10. The operational amplifier of claim 8, wherein the first current mirror circuit comprises a first current mirror transistor and a second current mirror transistor, and the operational amplifier further comprises:
a first cascode transistor, wherein a source terminal of the first cascode transistor is coupled to a drain terminal of the first current mirror transistor, and a drain terminal of the first cascode transistor is coupled to a gate terminal of the first current mirror transistor, to make the first current mirror transistor generate a first control voltage on the gate terminal of the first current mirror transistor according to the first current mirror input current, wherein the second current mirror transistor generates the first current mirror output current according to the first control voltage; and
a second cascode transistor, wherein a source terminal of the second cascode transistor is coupled to a drain terminal of the second current mirror transistor, and a drain terminal of the second cascode transistor is the amplifier output terminal;
wherein the drain terminal of the first current mirror transistor represents the first current input terminal, the drain terminal of the second current mirror transistor represents the first current output terminal, and the second terminal of the capacitor is coupled to the drain terminal of the first cascode transistor.

11. The operational amplifier of claim 1, wherein the at least one input transistor comprises a first input transistor and a second input transistor, the first input transistor is configured to generate a first input current according to a first input signal of the input signal, the second input transistor is configured to generate a second input current according to a second input signal of the input signal, and the at least one current mirror circuit comprises:
a first current mirror circuit, configured to generate a first current mirror output current on a first current output terminal of the first current mirror circuit according to a first current mirror input current received by a first current input terminal of the first current mirror circuit, wherein the first current mirror input current corresponds to the second input current, and the first current output terminal of the first current mirror circuit is coupled to the amplifier output terminal;
a second current mirror circuit, configured to generate a second current mirror output current on a second current output terminal of the second current mirror circuit according to a second current mirror input current received by a second current input terminal of the second current mirror circuit, wherein the second current mirror input current corresponds to the first input current; and
a third current mirror circuit, configured to generate a third current mirror output current on a third current output terminal of the third current mirror circuit according to a third current mirror input current received by a third current input terminal of the third current mirror circuit, wherein the third current mirror input current corresponds to the second current mirror output current, the third current input terminal of the third current mirror circuit is coupled to the second current output terminal of the second current mirror circuit, and the third current output terminal of the third current mirror circuit is coupled to the amplifier output terminal;
wherein the second terminal of the capacitor is coupled to the third current input terminal of the third current mirror circuit, to make the equivalent capacitance of the capacitor on the amplifier output terminal be multiplied by the third current mirror circuit.

12. The operational amplifier of claim 11, wherein the second current mirror comprises a first current mirror transistor and a second current mirror transistor, the third current mirror circuit comprises a third current mirror transistor and a fourth current mirror transistor, and the operational amplifier further comprises:
a first cascode transistor, wherein a source terminal of the first cascode transistor is coupled to a drain terminal of the first current mirror transistor, and a drain terminal of the first cascode transistor is coupled to a gate terminal of the first current mirror transistor, to make the first current mirror transistor generate a second control voltage on the gate terminal of the first current mirror transistor according to the second current mirror input current, wherein the second current mirror transistor generates the second current mirror output current according to the second control voltage; and
a second cascode transistor, wherein a source terminal of the second cascode transistor is coupled to a drain terminal of the second current mirror transistor;
a third cascode transistor, wherein a source terminal of the third cascode transistor is coupled to a drain terminal of the third current mirror transistor, and a drain terminal of the third cascode transistor is coupled to a gate terminal of the third current mirror transistor and a drain terminal of the second cascode transistor, to make the third current mirror transistor generate a third control voltage on the gate terminal of the third current mirror transistor according to the third current mirror input current, wherein the fourth current mirror transistor generates the third current mirror output current according to the third control voltage;
a fourth cascode transistor, wherein a source terminal of the fourth cascode transistor is coupled to a drain terminal of the fourth current mirror transistor, and a drain terminal of the fourth cascode transistor is the amplifier output terminal;
wherein the drain terminal of the first current mirror transistor represents the second current input terminal, the drain terminal of the second current mirror transistor represents the second current output terminal, the drain terminal of the third current mirror transistor represents the third current input terminal, the drain terminal of the fourth current mirror transistor represents the third current output terminal, and the second terminal of the capacitor is coupled to the drain terminal of the second current mirror transistor.

13. The operational amplifier of claim 11, wherein the second current mirror comprises a first current mirror transistor and a second current mirror transistor, the third current mirror circuit comprises a third current mirror transistor and a fourth current mirror transistor, and the operational amplifier further comprises:
a first cascode transistor, wherein a source terminal of the first cascode transistor is coupled to a drain terminal of the first current mirror transistor, and a drain terminal of the first cascode transistor is coupled to a gate terminal of the first current mirror transistor, to make the first current mirror transistor generate a second control voltage on the gate terminal of the first current mirror transistor according to the second current mirror input current, wherein the second current mirror transistor generates the second current mirror output current according to the second control voltage; and
a second cascode transistor, wherein a source terminal of the second cascode transistor is coupled to a drain terminal of the second current mirror transistor;
a third cascode transistor, wherein a source terminal of the third cascode transistor is coupled to a drain terminal of the third current mirror transistor, and a drain terminal of the third cascode transistor is coupled to a gate terminal of the third current mirror transistor and a drain terminal of the second cascode transistor, to make the third current mirror transistor generate a third control voltage on the gate terminal of the third current mirror transistor according to the third current mirror input current, wherein the fourth current mirror transistor generates the third current mirror output current according to the third control voltage;
a fourth cascode transistor, wherein a source terminal of the fourth cascode transistor is coupled to a drain terminal of the fourth current mirror transistor, and a drain terminal of the fourth cascode transistor is the amplifier output terminal;
wherein the drain terminal of the first current mirror transistor represents the second current input terminal, the drain terminal of the second current mirror transistor represents the second current output terminal, the drain terminal of the third current mirror transistor represents the third current input terminal, the drain terminal of the fourth current mirror transistor represents the third current output terminal, and the second terminal of the capacitor is coupled to the drain terminal of the second cascode transistor.

14. The operational amplifier of claim 11, wherein the second current mirror comprises a first current mirror transistor and a second current mirror transistor, the third current mirror circuit comprises a third current mirror transistor and a fourth current mirror transistor, and the operational amplifier further comprises:
a first cascode transistor, wherein a source terminal of the first cascode transistor is coupled to a drain terminal of the first current mirror transistor, and a drain terminal of the first cascode transistor is coupled to a gate terminal of the first current mirror transistor, to make the first current mirror transistor generate a second control voltage on the gate terminal of the first current mirror transistor according to the second current mirror input current, wherein the second current mirror transistor generates the second current mirror output current according to the second control voltage; and
a second cascode transistor, wherein a source terminal of the second cascode transistor is coupled to a drain terminal of the second current mirror transistor;
a third cascode transistor, wherein a source terminal of the third cascode transistor is coupled to a drain terminal of the third current mirror transistor, and a drain terminal of the third cascode transistor is coupled to a gate terminal of the third current mirror transistor and a drain terminal of the second cascode transistor, to make the third current mirror transistor generate a third control voltage on the gate terminal of the third current mirror transistor according to the third current mirror input current, wherein the fourth current mirror transistor generates the third current mirror output current according to the third control voltage;
a fourth cascode transistor, wherein a source terminal of the fourth cascode transistor is coupled to a drain terminal of the fourth current mirror transistor, and a drain terminal of the fourth cascode transistor is the amplifier output terminal;
wherein the drain terminal of the first current mirror transistor represents the second current input terminal, the drain terminal of the second current mirror transistor represents the second current output terminal, the drain terminal of the third current mirror transistor represents the third current input terminal, the drain terminal of the fourth current mirror transistor represents the third current output terminal, and the second terminal of the capacitor is coupled to the drain terminal of the third current mirror transistor.
